(19) United States
(12) Patent Application Publication
(10) Pub. No.: US 2011/0020975 A1
(43) Pub. Date: Jan. 27, 2011

(54) METHOD FOR MANUFACTURING PHOTODIODE DEVICE

(75) Inventors: Chan Shin Wu, Hukou Shiang (TW); Yung-Yi Tu, Taichung City (TW); Shan Hua Wu, Zhubei City (TW)

Correspondence Address: LIU & LIU, 444 S. FLOWER STREET SUITE 1750, LOS ANGELES, CA, 90071, US

(73) Assignee: SOLAPOINT CORPORATION, Hukou Shiang (TW)

(21) Appl. No.: 12/784,961

(22) Filed: May 21, 2010

(30) Foreign Application Priority Data
Jul. 27, 2009 (TW) 98125175

(51) Int. Cl. H01L 31/18

(52) U.S. Cl. 438/72; 257/E31.055

(57) ABSTRACT

A method of manufacturing photodiode device includes the following steps: providing a wafer having a substrate and an epitaxy layer, the substrate having a first surface and a second surface and the epitaxy layer formed on the first surface; forming a first conductive layer on the second surface of the substrate; forming a patterned conductive layer above the epitaxy layer; and etching the patterned conductive layer by a reactive ion etching (RIE) process performed under argon gas and helium gas.

### CROSS REFERENCE TO RELATED APPLICATIONS

This application claims priority to Taiwan Patent Application No. 98125175 entitled “METHOD FOR MANUFACTURING PHOTODIODE DEVICE”, filed on Jul. 27, 2009, which is incorporated herein by reference and assigned to the assignee herein.

### FIELD OF INVENTION

The invention is related to a method of manufacturing a photodiode device, especially to a method of manufacturing a photodiode device capable of improving photoelectric transformation efficiency, enhancing the reliability of the manufacturing process, and reducing production costs.

### BACKGROUND OF THE INVENTION

With the advent of the energy shortage, people gradually pay more attention to the techniques of power saving and the development of alternative energy, such as wind energy, water energy, solar energy, etc. Nowadays, the solar cell is widely used in various application fields due to its advantages of low pollution, easy operation, and long lifespan. Solar cell is a photodiode which is capable of absorbing sunlight by a P-N junction made of different semiconductor materials and converting the energy of sunlight into electricity by the photovoltaic effect.

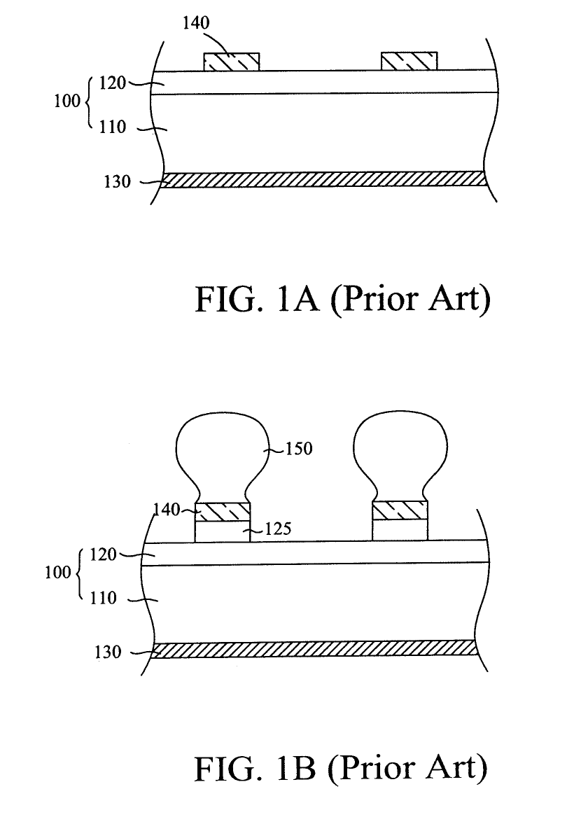

FIGS. 1A and 1B are flowcharts, in cross-sectional views, illustrating one conventional process of manufacturing the photodiode. Referring to FIG. 1A, a wafer 100 having a substrate 110 and an epitaxy layer 120 is provided, and then a first conductive layer 130 is formed on a bottom surface of the wafer 100 for use as an electrical connection at a later stage. Next, a first patterned conductive layer 140 with a thickness of about 5000 Å is formed on the epitaxy layer 120 by conventional metal deposition, microlithography and etching processes with a first photomask.

Next, referring to FIG. 1B, a plurality of epitaxy structure 125 are formed by etching the epitaxy layer 120 using the first patterned conductive layer 140 as a mask. A second patterned conductive layer 150 is then formed on the first patterned conductive layer 140 by an electroplating method with a second photomask, so as to increase the thickness of the whole conductive layer. Typically, the thickness of the second patterned conductive layer 150 is about 5 μm. Lastly, a conformal anti-reflective layer is formed on the wafer 100 and then etched by using a third photomask, so that a part of the second patterned conductive layer 150 can be exposed for use as an electrical connection at a later stage.

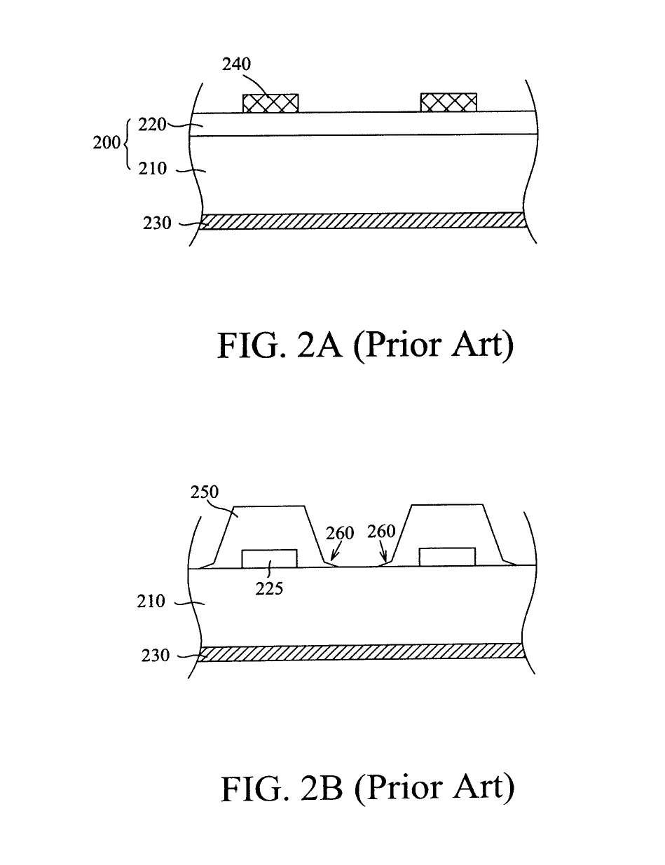

FIGS. 2A and 2B are flowcharts, in cross-sectional views, illustrating another conventional process of manufacturing the photodiode. Referring to FIG. 2A, a wafer 200 having a substrate 210 and an epitaxy layer 220 is provided, and then a first conductive layer 230 is formed on a bottom surface of the wafer 200 for use as an electrical connection at a later stage. Next, a first patterned photoresist layer 240 is formed on the epitaxy layer 220 by using a first photomask.

Next, as shown in FIG. 2B, a plurality of epitaxy structure 225 are formed by etching the epitaxy layer 220 using the patterned photoresist layer 240 as a mask. A patterned conductive layer 250 with a thickness of about 5 μm is then formed by an evaporation method with a second photomask, which at least covers the plurality of epitaxy structures 225. Lastly, a conformal anti-reflective layer is formed on the wafer 200 and then etched by using a third photomask, so that a part of the second patterned conductive layer 250 can be exposed for use as an electrical connection at a later stage. It should be noted that there are footing structures 260 formed at two bottom sides of the patterned conductive layer 250, and each of them has a thickness between about 1000 Å to about 3000 Å and a width between about 1 μm to about 2 μm. Generally, the footing structures 260 are inevitable to be formed on the edge of the metal line in the conventional evaporation and etching processes. However, the footing structures 260 have no contribution to the conductivity of the metal line due to their relatively high resistance, but may lead to an adverse effect on the reliability of the device. In addition, the footing structures 260 may obstruct part of incoming light, resulting in lower photoelectric transformation efficiency. Furthermore, both of the above-described conventional methods require at least three photomasks and therefore suffer from high manufacturing cost.

Therefore, it is necessary to provide a method of manufacturing a photodiode capable of not only improving the photoelectric transformation efficiency but also reducing the production cost.

### SUMMARY OF THE INVENTION

In light of the drawbacks of the prior arts, the present invention provides a method of manufacturing a photodiode device to improve photoelectric transformation efficiency, enhance the reliability of the manufacturing process, and reduce production costs.

According to one aspect of the present invention, a method of manufacturing a photodiode device is provided. The method includes the following steps: providing a wafer having a substrate and an epitaxy layer, the substrate having a first surface and a second surface and the epitaxy layer formed on the first surface; forming a first conductive layer on the second surface of the substrate; forming a patterned conductive layer above the epitaxy layer; and etching the patterned conductive layer by performing a reactive ion etching (RIE) process using a gas mixture of argon (Ar) gas and helium (He) gas as etchant to remove footing structures formed at two bottom sides of the patterned conductive layer.

In one embodiment, the method of the present invention further includes the following step: after the step of etching the patterned conductive layer, etching the epitaxy layer by using the patterned conductive layer to expose the first surface of the substrate. In this embodiment, the required number of the photomasks can be reduced by one as compared with the conventional manufacturing process.

In another embodiment, before the step of forming the patterned conductive layer, the epitaxy layer is patterned to form a plurality of epitaxy structures, wherein the patterned conductive layer at least covers the plurality of epitaxy structures.

The other aspects of the present invention, part of them will be described in the following description, part of them will be apparent from description, or can be known from the execution of the present invention. The aspects of the invention will be realized and attained by means of the elements and combinations particularly pointed out in the appended claims. It is to be understood that both the foregoing general description and the following detailed description are exemplary and explanatory only and are not restrictive of the invention, as claimed.

### BRIEF DESCRIPTION OF THE PICTURES

The foregoing aspects and many of the attendant advantages of this invention will become more readily appreciated as the same becomes better understood by reference to the following detailed description, when taken in conjunction with the accompanying pictures, wherein:

FIGS. 1A and 1B are flowcharts, in cross-sectional views, illustrating one conventional process of manufacturing the photodiode;

FIGS. 2A and 2B are flowcharts, in cross-sectional views, illustrating another conventional process of manufacturing the photodiode;

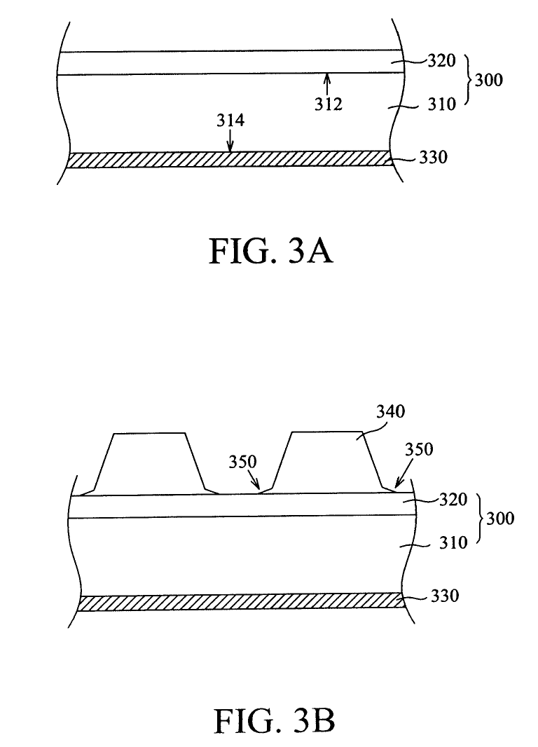

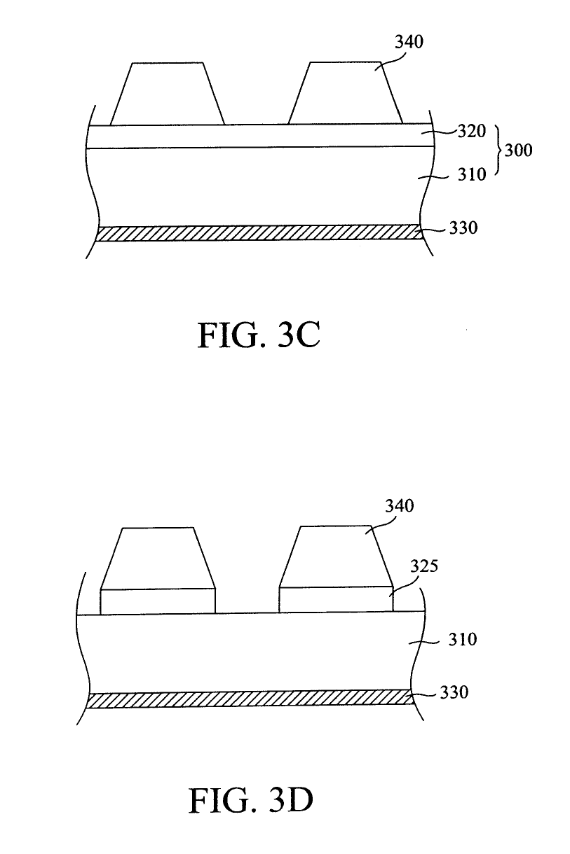

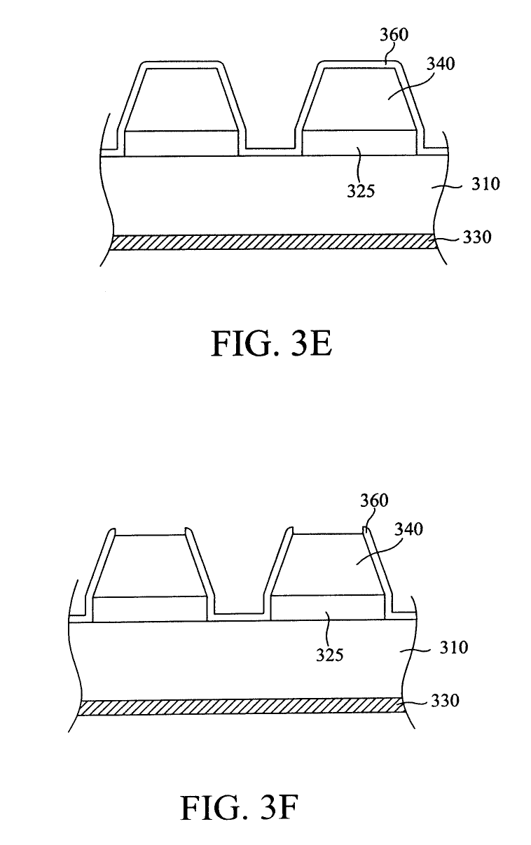

FIGS. 3A-3F are flowcharts, in cross-sectional views, illustrating the process of manufacturing a photodiode in accordance with one embodiment of the present invention; and

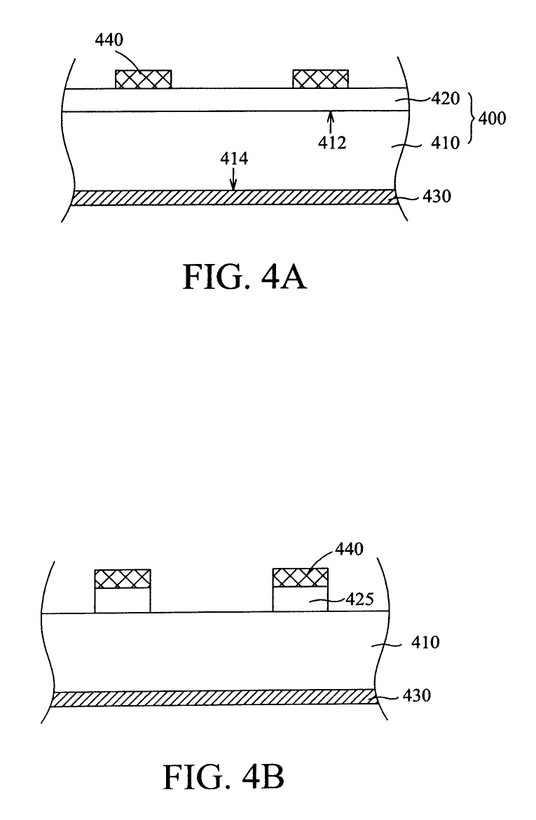

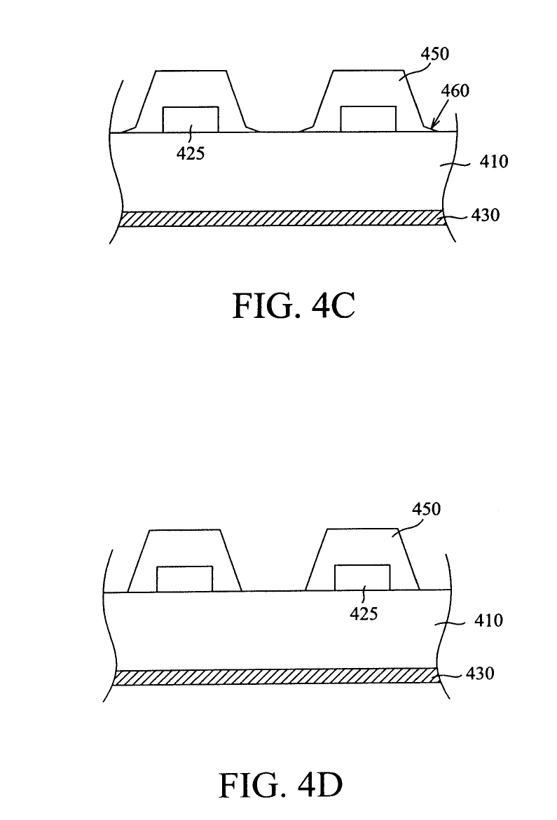

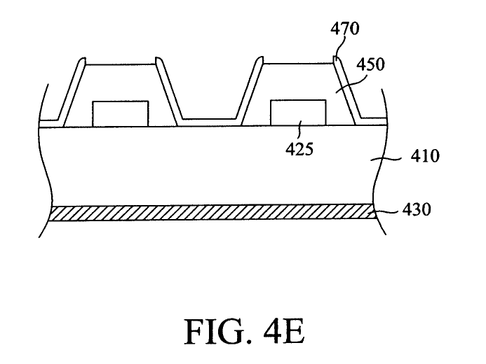

FIGS. 4A-4E are flowcharts, in cross-sectional views, illustrating the process of manufacturing a photodiode in accordance with another embodiment of the present invention.

### DETAILED DESCRIPTION OF THE INVENTION

The method of manufacturing a photodiode disclosed in the present invention has advantages of increasing photoelectric transformation efficiency, reducing the number of required photomasks, and lowering the production cost. To make the disclosure of the present invention more detailed and complete, references are made to the following description in conjunction with FIG. 3A to FIG. 4E. However, the drawings illustrated in the figures are not necessarily to scale and only intended to serve as illustrating embodiments of the invention, and the devices, elements, or operations in the following embodiments are provided for exemplary purposes only. In the following description, the unnecessary structure, material, procedures or steps that may make the subject matter of the present invention obscure will be omitted. Furthermore, it should be noted that when an element is referred to as being “on” another element, it can be directly on the other element or intervening elements may also be present, unless explicitly defined otherwise herein.

In the embodiments of the present invention, each layers on the substrate can be formed by the methods well known by those skilled in the art, such as deposition process, chemical vapor deposition process, plasma enhanced chemical vapor deposition (PECVD) process, atomic layer deposition (ALD) process, etc.

FIGS. 3A-3F are flowcharts, in cross-sectional views, illustrating the process of manufacturing a photodiode in accordance with one embodiment of the present invention. Referring to FIG. 3A, in one embodiment of the present invention, a wafer 300, which has a substrate 310 and an epitaxy layer 320 formed on a first surface 312 of the substrate 310, is provided. The substrate 310 can be any suitable semiconductor substrate, such as silicon substrate, germanium substrate, GaAs substrate, etc. The epitaxy layer 320 is a mulit-layer structure having at least one P-N junction, which is made of several different semiconductor materials having desirable lattice matching conditions and energy gaps. The epitaxy layer 320 can be formed by any suitable known film process, such as MOCVD. In addition, the epitaxy layer 320 can further include a plurality of transparent conductive layers interleaved between the plurality of P-N junctions respectively, for effectively collecting the photo-induced current.

Typically, the plurality of P-N junctions included in the epitaxy layer 320 are made of different semiconductor materials having different energy gaps for absorbing light beams of different wavelengths. For example, the epitaxy layer 320 can include a GalnP layer, a GaAs layer, and a GaInAs layer. In one embodiment, the P-N junction being closer to the substrate has a smaller energy gap than the P-N junction being further from the substrate, which can be used to absorb light of shorter wavelength. With these P-N junctions having different energy gaps, the absorption wavelength range can be widened, so as to improve the photoelectric transformation efficiency.

Next, a first conductive layer 330 is formed on a second surface 314 of the substrate 310, which can be formed of any suitable metal materials, such as Ti, Ag, Pt, Au, Sn, Ni, Cu, alloys thereof, or other suitable electrically conductive materials. The first conductive layer 330 can be formed by printing method or any vacuum plating techniques.

Referring to FIG. 3B, a patterned conductive layer 340, which can be made of any suitable electrically conductive materials (such as metal or metal alloy) with a thickness of about 4 μm to about 6 μm, is formed on the epitaxy layer 320 by the conventional metal deposition process (such as evaporation) and etching process. For example, the patterned conductive layer 340 shown in FIG. 3B can be formed by the following steps: forming a patterned photoresist layer (not shown) on the epitaxy layer 320; forming a second conductive layer (not shown) by evaporation process; and then removing the patterned photoresist layer and part of the second conductive layer positioned above the patterned photoresist layer by a lift-off process. The footing structures 350 may be formed at two bottom sides of the patterned conductive layer 340 due to some inherent limitations of the evaporation process, microlithography process, or etching process. Typically, the footing structure 350 has a thickness of about 1000 Å to about 3000 Å and a width of about 1 μm to about 2 μm.

Next, referring to FIG. 3C, the footing structures 350 are removed by etching the whole wafer 300 using dry etching techniques, such as reactive ion etching (RIE) process. In one embodiment of the present invention, for removing the footing structures 350, the RIE process is performed on the wafer 300 under the following conditions: pressure is 10-30 mTorr, power is 100-500 Watt, DC bias is 300-600V, and flow rate of the argon (Ar) gas and helium (He) gas is 15-25 sccm. Because this step can be performed on the whole wafer 300, no mask is required. In other embodiments of the present invention, before removing the footing structures 350 by RIE process, a protective layer (not shown) made of materials having low etching rate to inert gases (such as Ni, W, Mo, Ti, Ta, etc.) can be formed at top of the patterned conductive layer 340.

Referring to FIG. 3D, a plurality of epitaxy structures 325 can be formed by etching the epitaxy layer 320 using the patterned conductive layer 340 as a mask. In one embodiment, the etching depth can reach the first surface 312 of the substrate 310. The method of etching the epitaxy layer 320 can be any conventional wet etching processes. For example, the epitaxy layer 320 can be etched by NH₄OH solution or by an etchant prepared by mixing H₃PO₄, H₂O₂, and H₂O at a predetermined ratio.

Referring to FIG. 3E, an anti-reflective layer 360 is conformally formed for reducing reflections of incident light, so as to improve photoelectric transformation efficiency. The anti-reflective layer 360 can be a single-layer structure or a double-layer structure formed by any transparent material having a refractive index lower than that of the substrate 310, such as SiO₂, Si₃N₄, TiO₂, Al₂O₃, or the combination thereof. The thickness of the anti-reflective layer 360 can be varied depending upon the refractive index value or any specific needs. The method of forming the anti-reflective layer 360 can be any conventional deposition techniques, such as evaporation, sputtering, chemical vapor deposition, etc.

Next, referring to FIG. 3F, part of the anti-reflective layer 360 is removed by the conventional microlithography process, so as to expose the underlying patterned conductive layer 340 for use as an electrical connection at a later stage. The step of removing the part of the anti-reflective layer 360 may include the following steps: coating a photoresist layer (not shown) on the anti-reflective layer 360; patterning the photoresist layer by a pattern transferring technique (such as exposure and development processes) to define the locations at which the patterned conductive layer 340 is to be exposed; and etching the anti-reflective layer 360 by using the patterned photoresist layer as a mask, so as to obtain the structure shown in FIG. 3F.

In the embodiment shown in FIGS. 3A-3F, the footing structures, which are harmful to the photoelectric transformation efficiency, can be removed by using only two masks, thereby achieving higher operating performance and lower production cost.

FIGS. 4A-4E are flowcharts, in cross-sectional views, illustrating the process of manufacturing a photodiode in accordance with another embodiment of the present invention. Referring to FIG. 4A, in one embodiment of the present invention, a wafer 400, which has a substrate 410 and an epitaxy layer 420 formed on a first surface 412 of the substrate 410, is provided. The structures and materials of the substrate 410 and the epitaxy layer 420 can refer to the description given above. Next, a first conductive layer 430 is formed on a second surface 414 of the substrate 410 by, for example, printing method, vacuum plating technique, etc. Next, a patterned photoresist layer 440 can be formed on the epitaxy layer 420 to define the locations at which the epitaxy layer 420 is to be etched. The patterned photoresist layer 440 as shown in FIG. 4A can be formed by, for example, entirely coating a photoresist layer (not shown) on the epitaxy layer 420 and then patterning the photoresist layer by a pattern transferring technique (such as exposure and development processes).

Referring to FIG. 4B, a plurality of epitaxy structures 425 can be formed by etching the epitaxy layer 420 using the patterned photoresist layer 440 as a mask. The method of etching the epitaxy layer 420 can refer to the description given above. Next, referring to FIG. 4C, a patterned conductive layer 450 is formed to at least cover the plurality of epitaxy structures 425. The method of forming the patterned conductive layer 450 may include the following steps: forming a patterned photoresist layer (not shown) on the substrate 410 by the microlithography process (such as, spin-coating, exposure, development processes), wherein the patterned photoresist layer does not cover the epitaxy structures 425; forming a second conductive layer (not shown) by any conventional metal deposition process (such as evaporation) to cover the patterned photoresist layer and all of the epitaxy structures 425; and removing the patterned photoresist layer and part of the second conductive layer positioned above the patterned photoresist layer by a lift-off process, so as to form the patterned conductive layer 450 shown in FIG. 4C. Typically, when forming the patterned conductive layer 450, the footing structures 460 with a thickness of about 1000 Å to about 3000 Å and a width of about 1 μm to about 2 μm may be inevitable due to the inherent limitations of the manufacturing process.

Next, referring to FIG. 4D, the footing structures 450 are removed by etching the whole wafer 400 using dry etching techniques, such as reactive ion etching (RIE) process. In one embodiment of the present invention, for removing the footing structures 450, the RIE process is performed on the wafer 400 under the following conditions: etchant is a gas mixture of argon (Ar) gas and helium (He) gas, flow rate of Ar gas and He gas is 15-25 sccm, pressure is 10-30 mTorr, power is 100-500 Watt, and DC bias is 300-600V. Because this step can be performed on whole wafer 400, no mask is required. In other embodiments of the present invention, before removing the footing structures 460 by RIE process, a protective layer (not shown) made of materials having low etching rate to inert gases (such as Ni, W, Mo, Ti, Ta, etc.) can be formed at top of the patterned conductive layer 450.

Referring to FIG. 4E, a patterned anti-reflective layer 470 is formed on the substrate 410 to expose part of patterned conductive layer 450 for use as an electrical connection at a later stage. The step of forming the patterned anti-reflective layer 470 may include the following steps: forming a conformal anti-reflective layer (not shown) by the conventional deposition process (the material and detail thereof can refer to the description given above); forming a patterned photoresist layer on the conformal anti-reflective layer to define the locations at which the patterned conductive layer 450 is to be exposed; and etching the conformal anti-reflective layer by using the patterned photoresist layer as a mask, so as to obtain the patterned anti-reflective layer shown in FIG. 4E.

As compared with the conventional method of manufacturing the photodiode device, the method of the present invention can remove the footing structures formed at two bottom sides of the patterned conductive layer without adding an extra mask (even with less number of the masks), thereby preventing the photoelectric transformation efficiency from being degraded due to light shielding, and also enhancing the reliability of the manufacturing process and reducing production costs.

While this invention has been described with reference to the illustrative embodiments, these descriptions should not be construed in a limiting sense. Various modifications of the illustrative embodiment, as well as other embodiments of the invention, will be apparent upon reference to these descriptions. It is therefore contemplated that the appended claims will cover any such modifications or embodiments as falling within the true scope of the invention and its legal equivalents.

1. A method of manufacturing a photodiode device, comprising:
providing a wafer having a substrate and an epitaxy layer, the substrate having a first surface and a second surface and the epitaxy layer being formed on the first surface;
forming a first conductive layer on the second surface of the substrate;
forming a patterned conductive layer on the epitaxy layer; and
etching the patterned conductive layer by performing a reactive ion etching (RIE) process using a gas mixture of argon (Ar) and helium (He) as an etchant.

2. The method of claim 1, wherein the reactive ion etching process is performed at a pressure of about 0.01 Torr to about 0.03 Torr.

3. The method of claim 2, wherein the reactive ion etching process is performed with a flow rate of the gas mixture ranging from about 15 sccm to about 25 sccm.

4. The method of claim 3, wherein the reactive ion etching process is performed with a power level between about 100 Watts and about 500 Watts and a DC bias between about 300 volts and about 600 volts.

5. The method of claim 1, wherein after etching the patterned conductive layer, the method further comprises:
etching the epitaxy layer by using the patterned conductive layer as a mask to expose the first surface of the substrate.

6. The method of claim 1, wherein before forming the patterned conductive layer, the method further comprises:
patterning the epitaxy layer to form a plurality of epitaxy structures, wherein the plurality of epitaxy structures are covered by the patterned conductive layer.

7. The method of claim 5, further comprising:
conformally forming an anti-reflective layer on the patterned conductive layer; and
patterning the anti-reflective layer to expose a part of the patterned conductive layer.

8. The method of claim 6, further comprising:
conformally forming an anti-reflective layer on the patterned conductive layer; and
patterning the anti-reflective layer to expose a part of the patterned conductive layer.

9. The method of claim 1, wherein the epitaxy layer comprises a plurality of P-N junctions.

10. The method of claim 9, wherein the epitaxy layer further comprises a plurality of transparent conductive layers interleaved between the plurality of P-N junctions respectively.

11. The method of claim 10, wherein the plurality of P-N junctions have different energy levels, wherein one of the plurality of P-N junction being closer to the substrate has a smaller energy gap than another one of the plurality of P-N junction being further from the substrate.

12. The method of claim 11, wherein the plurality of P-N junctions comprises a GalnP layer, a GaAs layer, and a GaInAs layer.

13. The method of claim 1, wherein the substrate is a silicon substrate, a germanium substrate, or a GaAs substrate.

14. The method of claim 1, wherein the step of forming the patterned conductive layer comprises:
forming a patterned photoresist layer on the epitaxy layer;
depositing a second conductive layer on the patterned photoresist layer; and
removing the patterned photoresist layer and a part of the second conductive layer thereon by a lift-off process, so as to form the patterned conductive layer.

15. The method of claim 1, wherein a thickness of the patterned conductive layer is between about 4 μm and about 6 μm.

16. The method of claim 1, wherein the anti-reflective layer comprises a material selected from the group of SiO₂, Si₃N₄, TiO₂, and Al₂O₃.
